(19) United States
(12) Patent Application Publication
(10) Pub. No.: US 2021/0166647 A1
(43) Pub. Date: Jun. 3, 2021

(54) SHIFT REGISTER CIRCUITRY AND METHOD FOR DRIVING THE SAME, GATE ON ARRAY CIRCUITRY AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventors: Jian ZHAO, Beijing (CN); Hui WANG, Beijing (CN)

(73) Assignees: BOE TECHNOLOGY GROUP CO., LTD., Beijing (CN); HEFEI XINSHENG OPTOELECTRONICS TECHNOLOGY CO., LTD., Anhui (CN)

(21) Appl. No.: 15/779,386

(22) PCT Filed: Sep. 19, 2017
(86) PCT No.: PCT/CN2017/102174

§ 371 Date: May 25, 2018

(30) Foreign Application Priority Data
Jan. 3, 2017 (CN) 201710004565.0

(51) Int. Cl. G09G 3/36; G11C 19/28

(52) U.S. Cl. CPC G09G 3/3677; G11C 19/28; G09G 2310/0286; G09G 2300/0426; G09G 2300/0408; G09G 2330/027; G09G 2310/08; G09G 2320/0257

(57) ABSTRACT

A shift register circuitry and a method for driving the same, a GOA circuitry and a display device are provided. The shift register circuitry includes a GOA sub-circuit, where a gate drive signal output end of the GOA sub-circuit is configured to output a gate drive signal, and the GOA sub-circuit includes a pull-up node. The shift register circuitry further includes a shutdown control circuit coupled to the gate drive signal output end and the pull-up node of the GOA sub-circuit, a turn-on voltage output line and a turn-off voltage output line of the shift register circuitry and configured to, in response to a shutdown control signal, control the turn-on voltage output line to apply a turn-on voltage to the gate drive signal output end, and control the pull-up node to be coupled to the turn-off voltage output line.

### CROSS-REFFERENCE TO RELATED APPLICATION

This application claims priority to Chinese Patent Application No. 201710004565.0 filed Jan. 3, 2017, the disclosures of which are incorporated in their entirety by reference herein.

### TECHNICAL FIELD

The present disclosure relates to the field of display driving technology, and in particularly to a shift register circuitry and a method for driving the same, a Gate On Array (GOA) circuitry and a display device.

### BACKGROUND

In the related art, a gate driver IC has a Xon function, and the Xon function is implemented in such a manner that the Xon signal is set to a high level at the moment of shutdown, and all output channels of the gate driver IC are triggered to simultaneously output thin film transistor (TFT) turn-on voltages to turn on the TFTs in all rows, to release the residual charges on the pixel electrodes. However, there are certain problems with the related art. For example, all the voltages are in the falling state at the moment of shutdown. At this time, all channels simultaneously output the turn-on voltage (the voltage of the turn-on voltage is generally the same as the high voltage Vgh, which is about 27V), which may make the gate driver IC to drive with insufficient capacity and cannot turn on all the gate lines, and there will be line burns. In addition, the related art does not reset the potential of the pull-up node in the shift register unit in the gate drive circuit when the display panel is powered off, which may cause the characteristic drift of the transistor controlled by the pull-up node due to the residual voltage of the pull-up node after the shutdown, which may cause display failure.

### SUMMARY

In one aspect, a shift register circuitry is provided in the present disclosure, including: a GOA sub-circuit, where a gate drive signal output end of the GOA sub-circuit is configured to output a gate drive signal, and the GOA sub-circuit includes a pull-up node; a shutdown control circuit, coupled to the gate drive signal output end and the pull-up node of the GOA sub-circuit, a turn-on voltage output line and a turn-off voltage output line of the shift register circuitry, and configured to, in response to a shutdown control signal, control the turn-on voltage output line to apply a turn-on voltage to the gate drive signal output end, to turn on a thin film transistor of a pixel circuit coupled to a gate line in a corresponding row, and control the pull-up node to be coupled to the turn-off voltage output line, where the turn-off voltage output line is a ground line or a negative voltage output line.

Optionally, the shutdown control circuit includes: an output control circuit, coupled to the gate drive signal output end and the turn-on voltage output line, and configured to, in response to the shutdown control signal, control the turn-on voltage output line to apply the turn-on voltage to the gate drive signal output end.

Optionally, the shutdown control circuit further includes: a first pull-up node control circuit, coupled to the pull-up node and the turn-off voltage output line, and configured to, in response to the shutdown control signal, control the pull-up node to be coupled to the turn-off voltage output line.

Optionally, the output control circuit includes: an output control transistor, where a gate electrode of the output control transistor is coupled to a shutdown control signal output line configured to output the shutdown control signal, a first electrode of the output control transistor is coupled to the turn-on voltage output line, and a second electrode of the output control transistor is coupled to the gate drive signal output end; the first pull-up node control circuit includes a first pull-up node control transistor, where a gate of the first pull-up node control transistor is coupled to the shutdown control signal output line, a first electrode of the first pull-up node control transistor is coupled to the pull-up node, and a second electrode of the first pull-up node control transistor is coupled to the turn-off voltage output line.

Optionally, the GOA sub-circuit includes: a second pull-up node control circuit, coupled to an input end, a reset end, a first clock signal output end, a pull-down node and the pull-up node, and configured to control a potential of the pull-up node under control of the input end, the reset end, the first clock signal output end, the pull-down node and the pull-up node; a charge-discharge circuit, where a first end of the charge-discharge circuit is coupled to the pull-up node, and a second end of the charge-discharge circuit is coupled to the gate drive signal output end; a pull-down node control circuit, coupled to the first clock signal output end and the pull-up node, and configured to control a potential of the pull-down node under control of the first clock signal output end and the pull-up node; and an output circuit, coupled to the gate drive signal output end, the pull-up node, the pull-down node, the first clock signal output end, a second clock signal output end and a low-level output end; where the potential of the pull-up node is a first level and the output circuit is configured to control the gate drive signal output end to be coupled to the second clock signal output end; where the potential of the pull-down node and/or a first clock signal output by the first clock signal output end is a first level, and the output circuit is configured to control the gate drive signal output end to be coupled to the low-level output end.

Optionally, the GOA sub-circuit further includes: a reset circuit, coupled to the reset end, the gate drive signal output end and the low-level output end, and configured to control the gate drive signal output end to be coupled to the low-level output end or decoupled from the low-level output end under a control of the reset end.

Optionally, the pull-down node control circuit includes: a first pull-down node control transistor, where a gate electrode of the first pull-down node control transistor is coupled to the pull-up node, a first electrode of the first pull-down node control transistor is coupled to the pull-down node, and a second electrode of the first pull-down node control transistor is coupled to the low-level output end; a second pull-down node control transistor, where a gate electrode and a first electrode of the second pull-down node control transistor are both coupled to the first clock signal output end; a third pull-down node control transistor, where a gate electrode of the third pull-down node control transistor is coupled to a second electrode of the second pull-down node control transistor, and a second electrode of the third pull-down node control transistor is coupled to the pull-down node; and a fourth pull-down node control transistor, where a gate electrode of the fourth pull-down node control transistor is coupled to the pull-up node, a first electrode of the fourth pull-down node control transistor is coupled to the gate electrode of the third pull-down node control transistor, and a second electrode of the fourth pull-down node control transistor is coupled to the low-level output end; where the output circuit includes: a pull-up transistor, where a gate electrode of the pull-up transistor is coupled to the pull-up node, a first electrode of the pull-up transistor is coupled to the second clock signal output end, and a second electrode of the pull-up transistor is coupled to the gate drive signal output end; a pull-down transistor, where a gate electrode of the pull-down transistor is coupled to the pull-down node, a first electrode of the pull-down transistor is coupled to the gate drive signal output end, and a second electrode of the pull-down transistor is coupled to the low-level output end; and an output transistor, where a gate electrode of the output transistor is coupled to the first clock signal output end, a first electrode of the output transistor is coupled to the gate drive signal output end, and a second electrode of the output transistor is coupled to the low-level output end; where the shutdown control circuit is configured to, in response to the shutdown control signal, control the pull-up node to be coupled to the turn-off voltage output line, to turn off the first pull-down node control transistor and the pull-up transistor.

In another aspect, a method for driving the above shift register circuitry is further provided in the present disclosure, including: controlling by the shutdown control circuit, in response to a shutdown control signal, the turn-on voltage output line to apply a turn-on voltage to the gate drive signal output end, to turn on a thin film transistor of a pixel circuit coupled to a gate line in a corresponding row, and control the pull-up node to be coupled to the turn-off voltage output line, where the turn-off voltage output line is the ground line or the negative voltage output line.

In another aspect, a GOA circuitry is further provided in the present disclosure, including a plurality of shift register circuitries above coupled in a cascaded manner, where the input end of the GOA sub-circuit of the shift register circuitry in each stage excepting for a first stage is coupled to the gate drive signal output end of the GOA sub-circuit of the shift register circuitry in a previous stage; and the reset end of the GOA sub-circuit of the shift register circuitry in each stage excepting for a last stage is coupled to the gate drive signal output end of the GOA sub-circuit of the shift register circuitry in a following stage.

In another aspect, a display device including the above GOA circuitry is further provided in the present disclosure.

### BRIEF DESCRIPTION OF THE DRAWINGS

FIG. 1 is a schematic view of a shift register circuitry in at least one embodiment of the present disclosure;

FIG. 2 is a schematic view of a shift register circuitry in at least one embodiment of the present disclosure;

FIG. 3 is a schematic view of a shift register circuitry in at least one embodiment of the present disclosure;

FIG. 4 is a circuit diagram of a shift register circuitry in at least one embodiment of the present disclosure;

FIG. 5 is a working time sequence diagram of a shift register circuitry shown in FIG. 4 in a normal display state;

FIG. 6 is a working time sequence diagram of a shift register circuitry shown in FIG. 4 in a shutdown state; and

FIG. 7 is a schematic view of a GOA circuitry in at least one embodiment of the present disclosure.

### DETAILED DESCRIPTION

The present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

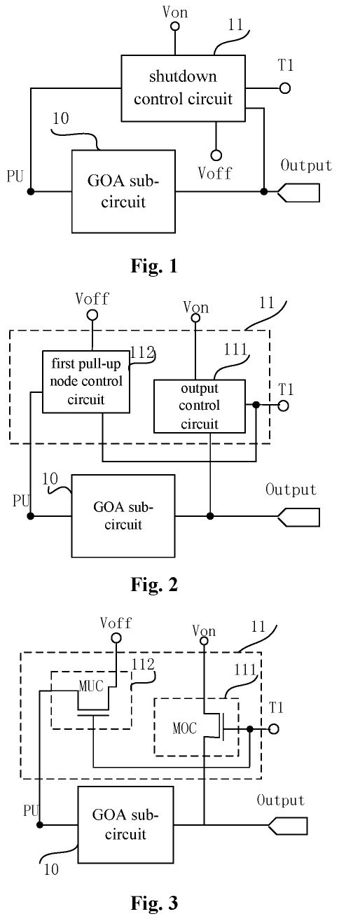

As shown in FIG. 1, a shift register circuitry is provided in at least one embodiment of the present disclosure, including: a GOA sub-circuit 10, where a gate drive signal output end OUTPUT of the GOA sub-circuit 10 is configured to output a gate drive signal, and the GOA sub-circuit 10 includes a pull-up node PU. The shift register circuitry further includes a shutdown control circuit 11.

A shutdown control circuit 11 is coupled to the gate drive signal output end OUTPUT and the pull-up node PU of the GOA sub-circuit 10, a turn-on voltage output line Von and a turn-off voltage output line Voff of the shift register circuitry. The shutdown control circuit 11 is configured to, in response to a shutdown control signal (e.g., after receiving a shutdown signal of the display panel), control the turn-on voltage output line Von to apply a turn-on voltage to the gate drive signal output end OUTPUT, to turn on all thin film transistors (not shown in FIG. 1) of a pixel circuit coupled to a gate line in a corresponding row, and control the pull-up node PU to be coupled to the turn-off voltage output line Voff. The turn-off voltage output line Voff is a ground line or a negative voltage output line.

In some embodiments of the present disclosure, the gate drive signal output end OUTPUT is coupled to a gate line in a corresponding row, and the thin film transistor of the pixel circuit coupled to the gate line in the corresponding row is generally a N-type thin film transistor, therefore the turn-on voltage output by the turn-on voltage output line Von is a high-level capable of turning on all the thin film transistors.

Because the transistor of the GOA sub-circuit 10 is generally a N-type transistor, in some embodiments of the present disclosure, the turn-off voltage output line may be a ground line or a negative voltage output line, so as to avoid the characteristic drift of the transistor controlled by the pull-up node PU or prevent the transistor controlled by the pull-up node PU from being turned on due to the residual voltage of the pull-up node PU after the shutdown, which may cause display failure.

According to the shift register circuitry in at least one embodiment of the present disclosure, the shutdown control circuit 11 controls the turn-on voltage output line Von to apply a turn-on voltage to the gate drive signal output end in the case that the display panel is shut down, so as to turn on all thin film transistors of the pixel circuit coupled to the gate line in the corresponding row, thereby releasing the residual charges on the pixel electrode and eliminating the shutdown burns. The shift register circuitry in at least one embodiment of the present disclosure turns on all the gate lines not by the gate drive IC, the technical issues in the related art, namely that the gate driver IC drives with insufficient capacity and cannot turn on all the gate lines and there will be line burns, may be solved. In addition, according to the shift register circuitry in at least one embodiment of the present disclosure, the shutdown control circuit 11 controls the pull-up node PU to be coupled to the turn-off voltage output line Voff, so as to avoid the characteristic drift of the transistor controlled by the pull-up node PU or prevent the transistor controlled by the pull-up node PU from being turned on due to the residual voltage of the pull-up node PU in the case that the display panel is shut down.

Optionally, the shutdown control circuit includes an output control circuit, coupled to the gate drive signal output end and the turn-on voltage output line. The shutdown control circuit is configured to, in response to the shutdown control signal (e.g., after receiving a shutdown signal of the display panel), control the turn-on voltage output line to apply the turn-on voltage to the gate drive signal output end.

In some embodiments of the present disclosure, the shutdown control circuit further includes: a first pull-up node control circuit, coupled to the pull-up node and the turn-off voltage output line, and configured to, in response to the shutdown control signal, control the pull-up node to be coupled to the turn-off voltage output line.

In some embodiments of the present disclosure, the shutdown control circuit 11 further includes: an output control circuit 111, coupled to the gate drive signal output end OUTPUT and the turn-on voltage output line Von. The shutdown control circuit 11 is configured to, in response to the shutdown control signal (e.g., after receiving a shutdown signal of the display panel), control the turn-on voltage output line Von to apply the turn-on voltage to the gate drive signal output end OUTPUT; and a first pull-up node control circuit 112, coupled to the pull-up node PU and the turn-off voltage output line Voff, and configured to, in response to the shutdown control signal, control the pull-up node PU to be coupled to the turn-off voltage output line Voff.

The shutdown control circuit 11 may control, through the output control circuit 111 and the first pull-up node control circuit 112, a voltage state of the gate drive signal output end OUTPUT and a voltage state of the pull-up node respectively in the case that the display panel is shut down.

In some embodiments of the present disclosure, the output control circuit includes: an output control transistor, where a gate electrode of the output control transistor is coupled to a shutdown control signal output line configured to output the shutdown control signal, a first electrode of the output control transistor is coupled to the turn-on voltage output line, and a second electrode of the output control transistor is coupled to the gate drive signal output end. The first pull-up node control circuit includes a first pull-up node control transistor, where a gate of the first pull-up node control transistor is coupled to the shutdown control signal output line, a first electrode of the first pull-up node control transistor is coupled to the pull-up node PU, and a second electrode of the first pull-up node control transistor is coupled to the turn-off voltage output line.

As shown in FIG. 3, the output control circuit 111 includes: an output control transistor MOC, where a gate electrode of the output control transistor is coupled to a shutdown control signal output line T1 configured to output the shutdown control signal, a source electrode of the output control transistor is coupled to the turn-on voltage output line Von, and a drain electrode of the output control transistor is coupled to the gate drive signal output end OUTPUT. The first pull-up node control circuit 112 includes a first pull-up node control transistor MUC, where a gate of the first pull-up node control transistor is coupled to the shutdown control signal output line T1, a source electrode of the first pull-up node control transistor is coupled to the pull-up node PU, and a drain electrode of the first pull-up node control transistor is coupled to the turn-off voltage output line Voff.

In some embodiments of the present disclosure, the GOA sub-circuit 10 includes: a second pull-up node control circuit, coupled to an input end, a reset end, a first clock signal output end, a pull-down node and the pull-up node, and configured to control a potential of the pull-up node under control of the input end, the reset end, the first clock signal output end, the pull-down node and the pull-up node; a charge-discharge circuit, where a first end of the charge-discharge circuit is coupled to the pull-up node, and a second end of the charge-discharge circuit is coupled to the gate drive signal output end; a pull-down node control circuit, coupled to the first clock signal output end and the pull-up node, and configured to control a potential of the pull-down node under control of the first clock signal output end and the pull-up node; and an output circuit, coupled to the gate drive signal output end, the pull-up node, the pull-down node, the first clock signal output end, a second clock signal output end and a low-level output end. In the case that the potential of the pull-up node is a first level, the output circuit is configured to control the gate drive signal output end to be coupled to the second clock signal output end. In the case that the potential of the pull-down node and/or a first clock signal output by the first clock signal output end is a first level, and the output circuit is configured to control the gate drive signal output end to be coupled to the low-level output end.

In some embodiments of the present disclosure, the GOA sub-circuit further includes: a reset circuit, coupled to the reset end, the gate drive signal output end and the low-level output end, and configured to control the gate drive signal output end to be coupled to the low-level output end or decoupled from the low-level output end under a control of the reset end.

In some embodiments of the present disclosure, the pull-down node control circuit includes: a first pull-down node control transistor, where a gate electrode of the first pull-down node control transistor is coupled to the pull-up node, a first electrode of the first pull-down node control transistor is coupled to the pull-down node, and a second electrode of the first pull-down node control transistor is coupled to the low-level output end; a second pull-down node control transistor, where a gate electrode and a first electrode of the second pull-down node control transistor are both coupled to the first clock signal output end; a third pull-down node control transistor, where a gate electrode of the third pull-down node control transistor is coupled to a second electrode of the second pull-down node control transistor, and a second electrode of the third pull-down node control transistor is coupled to the pull-down node; and a fourth pull-down node control transistor, where a gate electrode of the fourth pull-down node control transistor is coupled to the pull-up node, a first electrode of the fourth pull-down node control transistor is coupled to the gate electrode of the third pull-down node control transistor, and a second electrode of the fourth pull-down node control transistor is coupled to the low-level output end.

The output circuit includes: a pull-up transistor, where a gate electrode of the pull-up transistor is coupled to the pull-up node, a first electrode of the pull-up transistor is coupled to the second clock signal output end, and a second electrode of the pull-up transistor is coupled to the gate drive signal output end; a pull-down transistor, where a gate electrode of the pull-down transistor is coupled to the pull-down node, a first electrode of the pull-down transistor is coupled to the gate drive signal output end, and a second electrode of the pull-down transistor is coupled to the low-level output end; and an output transistor, where a gate electrode of the output transistor is coupled to the first clock signal output end, a first electrode of the output transistor is coupled to the gate drive signal output end, and a second electrode of the output transistor is coupled to the low-level output end.

The shutdown control circuit is configured to, in response to the shutdown control signal, control the pull-up node to be coupled to the turn-off voltage output line, so as to turn off the first pull-down node control transistor and the pull-up transistor.

In the case of receiving the shutdown control signal, the shutdown control circuit pulls down the potential of the pull-up node, so as to turn off the first pull-down node control transistor and the pull-up transistor.

The shift register circuitry provided in the present disclosure will be described in details in conjunction with the following embodiments.

In compared with the shift register circuitry in the related art, a peripheral control line of the GOA sub-circuit in at least one embodiment of the present disclosure is further provided with the shutdown control signal output line and the turn-on voltage output line Von.

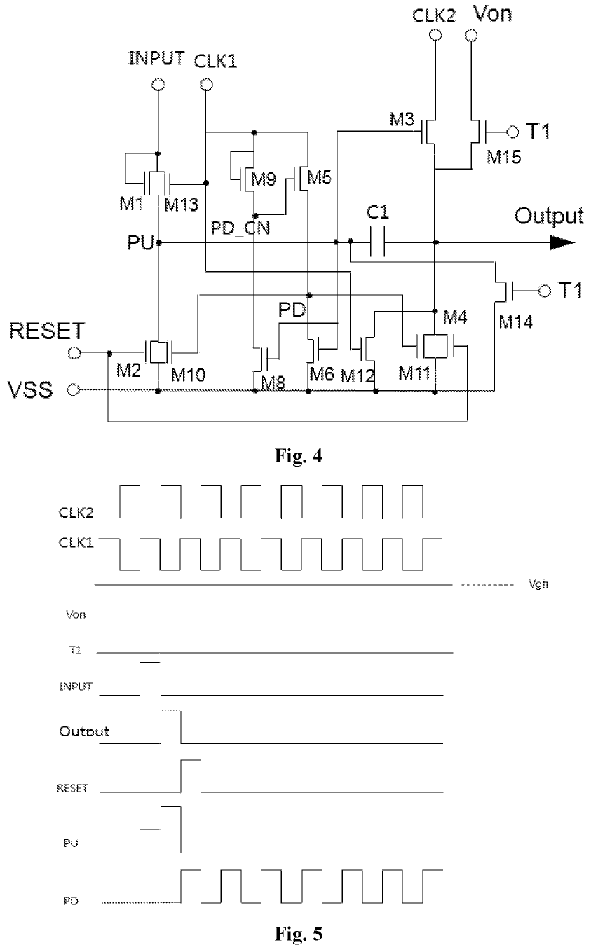

Taking a drive circuit of a shift register circuitry in a N^{th} (N is an odd number) stage as an example, as shown in FIG. 4, the shift register circuitry in at least one embodiment of the present disclosure includes 14 TFTs, one capacitor, two clock signals (a first clock signal CLK1 and a second clock signal CLK2), a turn-on voltage output line Von, a shutdown control signal output line T1 (configured to eliminate the shutdown burns), an input end, a low-level output end, a reset end and a gate drive signal output end OUTPUT. The VSS is configured to output a DC low-level signal. The CLK1 and CLK2 (controls the shift register circuitry alternately) has the same period and different amplitudes. The CLK1 and CLK2 are opposite in phase. It should be noted that, the shift register circuitry in a (N+1)^{th} (N is an odd number) stage is a shift register circuitry in an even-numbered stage, and in compared with the shift register circuitry in the N^{th} stage, the positions of the CLK1 and CLK2 interchanged, and the other structures are the same, and the detailed description thereof is omitted herein.

In FIG. 4, the node marked with “PU” is a pull-up node, the node marked with “PD” is a pull-down node, and the node marked with “PD_CN” is a pull-down control node.

In FIG. 4, the turn-off voltage output line is the low-level output line VSS, i.e., the turn-off voltage is a low level. The low level may be a ground level or a negative voltage.

In some embodiments of the present disclosure, as shown in FIG. 4, M15 is an output control transistor, M14 is a first pull-up node control transistor, M6 is a first pull-down node control transistor, M9 is a second pull-down node control transistor, M5 is a third pull-down node control transistor, M8 is a fourth pull-down node control transistor, M3 is a pull-up transistor, M11 is a pull-down transistor, and M12 is an output transistor. The second pull-up node control circuit includes an input transistor M1, a reset transistor M2, a second pull-up node control transistor M13 and a third pull-up node control transistor M10. The reset circuit includes an output reset transistor M4, and the charge-discharge circuit includes a storage capacitor C1.

In FIG. 4, all the transistors are N-type transistors. In the case that the first electrode is a source electrode, the second electrode is a drain electrode. In the case that the first electrode is a drain electrode, the second electrode is a source electrode.

The normal display time sequence will be described hereinafter by taking a shift register circuitry in the N^{th} (N is an odd number) stage as an example. In the case that the liquid crystal display panel displays normally. FIG. 5 is a working time sequence diagram of the shift register circuitry in the N^{th} stage in the case that the liquid crystal display panel displays normally. T1 outputs a low level, M14 and M15 are turned off, M3 is turned on in response to an input signal input by INPUT, and CLK2 is input to OUTPUT, to generate a gate drive signal. After a reset signal output by RESET is input, M1 is turned off, M2 is turned on, PU is coupled to VSS, a potential of PU is pulled down to a low level, and M3 is turned off. At this time, the CLK1 is a high-level signal, M9 is turned on, the potential of PD_CN is set to a high-level, M5 is turned on, the potential of PD is enhanced to a high-level, M11 is turned on, OUTPUT is set to a low level through the low level output by VSS. The rest may be done in a same manner, the shift register circuitries in the N^{th} stage, the (N+1)^{th} stage and (N+2)^{th} stage may generate in sequence the corresponding gate drive signals to drive the liquid crystal panel, so as to enable the display panel displays normally.

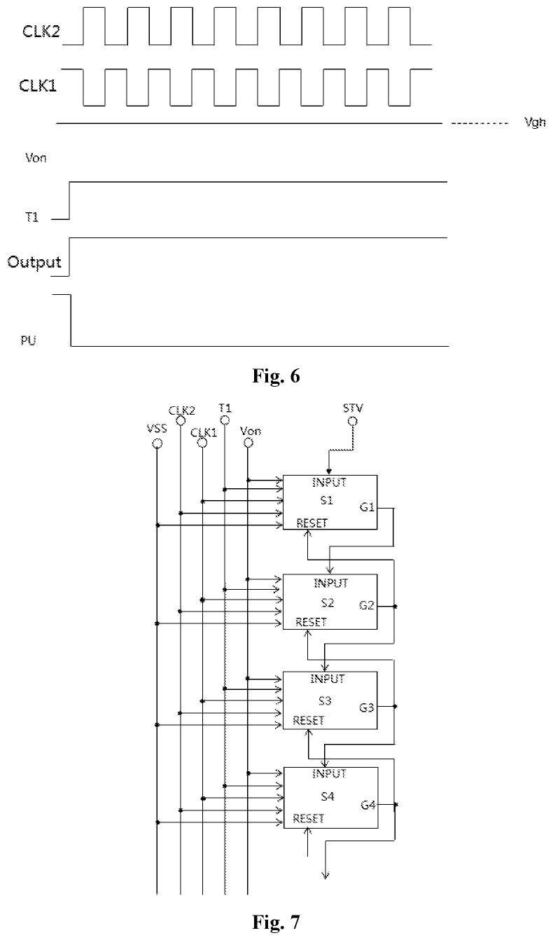

The time sequence at the shutdown moment will be described hereinafter by taking a shift register circuitry in the N^{th} (N is an odd number) stage as an example. FIG. 6 is a working time sequence diagram of the shift register circuitry in the N^{th} stage at the moment when the liquid crystal panel is shut down. At the shutdown moment, T1 outputs a high level signal, M14 and M15 are turned on, the potential of PU is pulled down by VSS to a low level, M3 is turned off. At this time, the gate drive signal output by OUTPUT turns to be a turn-on voltage output by Von (the value of the turn-on voltage output by Von is the same as the high level Vgh, which is about 27v), the TFT coupled to the corresponding gate line (the TFT is within the pixel circuit) is turned on, so as to release the charges on the pixel electrode and eliminate the shutdown burns. The rest may be done in a same manner, the shift register circuitries in the N^{th} stage, the (N+1)^{th} stage and (N+2)^{th} stage may generate the corresponding gate drive signals. The TFTs within the AA region (active area) of the liquid crystal panel and coupled to all gate lines are turned on, and meanwhile the charges on the pixel electrode are released, so as to eliminate the shutdown burns for the entire display panel. It should be noted that, at the shutdown moment, in response to the signal output by T1, M15 is turned on, the potential of PU is pulled down through VSS, so as to turn off M3 and enable OUTPUT to output a turn-on voltage. More importantly, the potential of PU is pulled down at the shutdown moment, thereby prevent the TFT characteristics of M3, M6 and other TFTs within the shift register circuitry from being adversely affected by the residual voltage on PU. In the case that PU is not discharged, M3 and M6 may be turned on by accident, and the TFT characteristics of M3 and M6 may be drifted correspondingly. As a result, the display failure may occur, and quality of the display panel may be adversely affected.

A method for driving the shift register circuitry hereinabove is provided in some embodiments of the present disclosure, including: controlling by the shutdown control circuit, in response to a shutdown control signal, the turn-on voltage output line to apply a turn-on voltage to the gate drive signal output end OUTPUT, to turn on a thin film transistor of a pixel circuit coupled to a gate line in a corresponding row, and control the pull-up node to be coupled to the turn-off voltage output line, where the turn-off voltage output line is the ground line or the negative voltage output line.

A GOA circuitry is provided in some embodiments of the present disclosure, including a plurality of shift register circuitries hereinabove which are coupled in a cascaded manner.

In some embodiments of the present disclosure, the input end of the GOA sub-circuit of the shift register circuitry in each stage excepting for a first stage is coupled to the gate drive signal output end of the GOA sub-circuit of the shift register circuitry in a previous stage, and the reset end of the GOA sub-circuit of the shift register circuitry in each stage excepting for a last stage is coupled to the gate drive signal output end of the GOA sub-circuit of the shift register circuitry in a following stage.

As shown in FIG. 7, S1 represents a shift register circuitry in the first stage, S2 represents a shift register circuitry in the second stage, S3 represents a shift register circuitry in third first stage, S4 represents a shift register circuitry in the fourth stage, VSS is a low-level output end, CLK1 is a first clock signal, CLK2 is a second clock signal, T1 is a shutdown control signal output line, and Von is a turn-on voltage output line. An initial signal STV is input to an input end INPUT of S1. G1 represents a gate drive signal output end of S1. A reset end of S1 is coupled to a gate drive signal output end G2 of S2. G1 is coupled to an input end of S2. G2 is coupled to an input end of S3. A reset end of S2 is coupled to a gate drive signal output end G3 of S3. G3 is coupled to an input end of S4. G4 is coupled to a reset end of S3.

A display device is further provided in some embodiments of the present disclosure, including the above GOA circuitry.

According to the shift register circuitry and the method for driving the same, the GOA circuitry and the display device in at least one embodiment of the present disclosure, the shutdown control circuit controls the turn-on voltage output line to apply a turn-on voltage to the gate drive signal output end in the case that the display panel is shut down, so as to turn on all thin film transistors of the pixel circuit coupled to the gate line in the corresponding row, thereby releasing the residual charges on the pixel electrode and eliminating the shutdown burns. The shift register circuitry in at least one embodiment of the present disclosure turns on all the gate lines not by the gate drive IC, the technical issues in the related art, namely that the gate driver IC drives with insufficient capacity and cannot turn on all the gate lines and there will be line burns, may be solved. In addition, according to the shift register circuitry in at least one embodiment of the present disclosure, the shutdown control circuit controls the pull-up node to be coupled to the turn-off voltage output line, so as to avoid the characteristic drift of the transistor controlled by the pull-up node or prevent the transistor controlled by the pull-up node from being turned on due to the residual voltage of the pull-up node in the case that the display panel is shut down.

The above are merely the preferred embodiments of the present disclosure. A person skilled in the art may make further modifications and improvements without departing from the principle of the present disclosure, and these modifications and improvements shall also fall within the scope of the present disclosure.

1. A shift register circuitry, comprising:
a Gate On Array (GOA) sub-circuit, wherein a gate drive signal output end of the GOA sub-circuit is configured to output a gate drive signal, and the GOA sub-circuit comprises a pull-up node;
a shutdown control circuit, coupled to the gate drive signal output end and the pull-up node of the GOA sub-circuit, a turn-on voltage output line and a turn-off voltage output line of the shift register circuitry, and configured to, in response to a shutdown control signal, control the turn-on voltage output line to apply a turn-on voltage to the gate drive signal output end, to turn on a thin film transistor of a pixel circuit coupled to a gate line in a corresponding row, and control the pull-up node to be coupled to the turn-off voltage output line, wherein the turn-off voltage output line is a ground line or a negative voltage output line.

2. The shift register circuitry according to claim 1, wherein the shutdown control circuit comprises:
an output control circuit, coupled to the gate drive signal output end and the turn-on voltage output line, and configured to, in response to the shutdown control signal, control the turn-on voltage output line to apply the turn-on voltage to the gate drive signal output end.

3. The shift register circuitry according to claim 2, wherein the shutdown control circuit further comprises:
a first pull-up node control circuit, coupled to the pull-up node and the turn-off voltage output line, and configured to, in response to the shutdown control signal, control the pull-up node to be coupled to the turn-off voltage output line.

4. The shift register circuitry according to claim 3, wherein the output control circuit comprises:
an output control transistor, wherein a gate electrode of the output control transistor is coupled to a shutdown control signal output line configured to output the shutdown control signal, a first electrode of the output control transistor is coupled to the turn-on voltage output line, and a second electrode of the output control transistor is coupled to the gate drive signal output end;
the first pull-up node control circuit comprises a first pull-up node control transistor, wherein a gate of the first pull-up node control transistor is coupled to the shutdown control signal output line, a first electrode of the first pull-up node control transistor is coupled to the pull-up node, and a second electrode of the first pull-up node control transistor is coupled to the turn-off voltage output line.

5. The shift register circuitry according to claim 1, wherein the GOA sub-circuit comprises:
a second pull-up node control circuit, coupled to an input end, a reset end, a first clock signal output end, a pull-down node and the pull-up node, and configured to control a potential of the pull-up node under control of the input end, the reset end, the first clock signal output end, the pull-down node and the pull-up node;
a charge-discharge circuit, wherein a first end of the charge-discharge circuit is coupled to the pull-up node, and a second end of the charge-discharge circuit is coupled to the gate drive signal output end;
a pull-down node control circuit, coupled to the first clock signal output end and the pull-up node, and configured to control a potential of the pull-down node under control of the first clock signal output end and the pull-up node; and
an output circuit, coupled to the gate drive signal output end, the pull-up node, the pull-down node, the first clock signal output end, a second clock signal output end and a low-level output end;
wherein the potential of the pull-up node is a first level and the output circuit is configured to control the gate drive signal output end to be coupled to the second clock signal output end.

6. The shift register circuitry according to claim 5, wherein the GOA sub-circuit further comprises:
a reset circuit, coupled to the reset end, the gate drive signal output end and the low-level output end, and configured to control the gate drive signal output end to be coupled to the low-level output end or decoupled from the low-level output end under a control of the reset end.

7. The shift register circuitry according to claim 5, wherein the pull-down node control circuit comprises:
a first pull-down node control transistor, wherein a gate electrode of the first pull-down node control transistor is coupled to the pull-up node, a first electrode of the first pull-down node control transistor is coupled to the pull-down node, and a second electrode of the first pull-down node control transistor is coupled to the low-level output end;
a second pull-down node control transistor, wherein a gate electrode and a first electrode of the second pull-down node control transistor are both coupled to the first clock signal output end;
a third pull-down node control transistor, wherein a gate electrode of the third pull-down node control transistor is coupled to a second electrode of the second pull-down node control transistor, and a second electrode of the third pull-down node control transistor is coupled to the pull-down node; and
a fourth pull-down node control transistor, wherein a gate electrode of the fourth pull-down node control transistor is coupled to the pull-up node, a first electrode of the fourth pull-down node control transistor is coupled to the gate electrode of the third pull-down node control transistor, and a second electrode of the fourth pull-down node control transistor is coupled to the low-level output end;
wherein the output circuit comprises:
a pull-up transistor, wherein a gate electrode of the pull-up transistor is coupled to the pull-up node, a first electrode of the pull-up transistor is coupled to the second clock signal output end, and a second electrode of the pull-up transistor is coupled to the gate drive signal output end;
a pull-down transistor, wherein a gate electrode of the pull-down transistor is coupled to the pull-down node, a first electrode of the pull-down transistor is coupled to the gate drive signal output end, and a second electrode of the pull-down transistor is coupled to the low-level output end; and
an output transistor, wherein a gate electrode of the output transistor is coupled to the first clock signal output end, a first electrode of the output transistor is coupled to the gate drive signal output end, and a second electrode of the output transistor is coupled to the low-level output end;
wherein the shutdown control circuit is configured to, in response to the shutdown control signal, control the pull-up node to be coupled to the turn-off voltage output line, to turn off the first pull-down node control transistor and the pull-up transistor.

8. The shift register circuitry according to claim 1, wherein the GOA sub-circuit comprises:
a second pull-up node control circuit, coupled to an input end, a reset end, a first clock signal output end, a pull-down node and the pull-up node, and configured to control a potential of the pull-up node under control of the input end, the reset end, the first clock signal output end, the pull-down node and the pull-up node;
a charge-discharge circuit, wherein a first end of the charge-discharge circuit is coupled to the pull-up node, and a second end of the charge-discharge circuit is coupled to the gate drive signal output end;
a pull-down node control circuit, coupled to the first clock signal output end and the pull-up node, and configured to control a potential of the pull-down node under control of the first clock signal output end and the pull-up node; and
an output circuit, coupled to the gate drive signal output end, the pull-up node, the pull-down node, the first clock signal output end, a second clock signal output end and a low-level output end;
wherein the potential of the pull-down node and/or a first clock signal output by the first clock signal output end is a first level, and the output circuit is configured to control the gate drive signal output end to be coupled to the low-level output end.

9. The shift register circuitry according to claim 8, wherein the GOA sub-circuit further comprises:
a reset circuit, coupled to the reset end, the gate drive signal output end and the low-level output end, and configured to control the gate drive signal output end to be coupled to the low-level output end or decoupled from the low-level output end under a control of the reset end.

10. The shift register circuitry according to claim 8, wherein the pull-down node control circuit comprises:
a first pull-down node control transistor, wherein a gate electrode of the first pull-down node control transistor is coupled to the pull-up node, a first electrode of the first pull-down node control transistor is coupled to the pull-down node, and a second electrode of the first pull-down node control transistor is coupled to the low-level output end;
a second pull-down node control transistor, wherein a gate electrode and a first electrode of the second pull-down node control transistor are both coupled to the first clock signal output end;
a third pull-down node control transistor, wherein a gate electrode of the third pull-down node control transistor is coupled to a second electrode of the second pull-down node control transistor, and a second electrode of the third pull-down node control transistor is coupled to the pull-down node; and
a fourth pull-down node control transistor, wherein a gate electrode of the fourth pull-down node control transistor is coupled to the pull-up node, a first electrode of the fourth pull-down node control transistor is coupled to the gate electrode of the third pull-down node control transistor, and a second electrode of the fourth pull-down node control transistor is coupled to the low-level output end;
wherein the output circuit comprises:
a pull-up transistor, wherein a gate electrode of the pull-up transistor is coupled to the pull-up node, a first electrode of the pull-up transistor is coupled to the second clock signal output end, and a second electrode of the pull-up transistor is coupled to the gate drive signal output end;
a pull-down transistor, wherein a gate electrode of the pull-down transistor is coupled to the pull-down node, a first electrode of the pull-down transistor is coupled to the gate drive signal output end, and a second electrode of the pull-down transistor is coupled to the low-level output end; and
an output transistor, wherein a gate electrode of the output transistor is coupled to the first clock signal output end, a first electrode of the output transistor is coupled to the gate drive signal output end, and a second electrode of the output transistor is coupled to the low-level output end;
wherein the shutdown control circuit is configured to, in response to the shutdown control signal, control the pull-up node to be coupled to the turn-off voltage output line, to turn off the first pull-down node control transistor and the pull-up transistor.

11. A method for driving the shift register circuitry according to claim 1, comprising:
controlling by the shutdown control circuit, in response to a shutdown control signal, the turn-on voltage output line to apply a turn-on voltage to the gate drive signal output end, to turn on a thin film transistor of a pixel circuit coupled to a gate line in a corresponding row, and control the pull-up node to be coupled to the turn-off voltage output line, wherein the turn-off voltage output line is the ground line or the negative voltage output line.

12. A Gate On Array (GOA) circuitry, comprising a plurality of shift register circuitries according to any claim 1 coupled in a cascaded manner, wherein
the input end of the GOA sub-circuit of the shift register circuitry in each stage excepting for a first stage is coupled to the gate drive signal output end of the GOA sub-circuit of the shift register circuitry in a previous stage; and
the reset end of the GOA sub-circuit of the shift register circuitry in each stage excepting for a last stage is coupled to the gate drive signal output end of the GOA sub-circuit of the shift register circuitry in a following stage.

13. A display device comprising the GOA circuitry according to claim 12.
